(19) United States
(12) Patent Application Publication
(10) Pub. No.: US 2026/0066032 A1
(43) Pub. Date: Mar. 5, 2026

(54) MEMORY PACKAGES WITH DYNAMICALLY ALLOCATED ERROR CORRECTION INFORMATION

(71) Applicant: Micron Technology, Inc., Boise, ID (US)

(72) Inventors: Navid Lashkarian, Pleasanton, CA (US); Randall J. Rooney, Boise, ID (US); Matthew A. Prather, Boise, ID (US); Anthony D. Veches, Boise, ID (US); Sujeet Ayyapureddi, Boise, ID (US)

(73) Assignee: Micron Technology, Inc., Boise, ID (US)

(21) Appl. No.: 19/290,877

(22) Filed: Aug. 5, 2025

Related U.S. Application Data
(60) Provisional application No. 63/689,068, filed on Aug. 30, 2024.

(51) Int. Cl. G11C 29/52; G11C 11/4093; G11C 11/4096

(52) U.S. Cl. CPC G11C 29/52; G11C 11/4093; G11C 11/4096

(57) ABSTRACT

A memory package may include multiple memory devices and a buffer die. In some examples, the buffer die and/or one or more of the memory devices may include an error correction code (ECC) circuit and/or a device health analysis circuit (DHAC). In some examples, memory devices may store ECC data for one or more other memory devices in the memory package. In some examples, memory arrays of the memory devices may be reorganized (reconfigured) to store more or less ECC data to dynamically allocate space to ECC data. In some examples, how much ECC data is stored for a memory device may be based, at least in part, on the error rate of the memory device.

### CROSS REFERENCE TO RELATED APPLICATION(S)

This application claims the benefit under 35 U.S.C. § 119 of the earlier filing date of U.S. Provisional Application No. 63/689,068 filed Aug. 30, 2024, the entire contents of which is hereby incorporated by reference in its entirety for any purpose.

### BACKGROUND

This disclosure relates generally to semiconductor devices, and more specifically to semiconductor memory devices. In particular, the disclosure relates to memory, such as dynamic random access memory (DRAM). Information may be stored in memory cells, which may be organized into rows (word lines) and columns (bit lines) of an array. Various types of information may be stored in the array, such as data, error correction code (ECC) data, and metadata. The data may be information provided by an external device (e.g., controller, processor, host system). The ECC data may provide information that may be used to detect and/or correct errors in the data. The metadata may provide information about the data, ECC data, the memory device, and/or a device in communication with the memory device (e.g., a controller).

Semiconductor memory devices may store information in multiple memory cells. The information may be stored as a binary code, and each memory cell may store a single bit of information as either a logical high (e.g., a “1”) or a logical low (e.g., a “0”). The memory cells may be organized at the intersection of word lines (rows) and bit lines (columns) an array. The memory may further be organized into one or more memory banks. The banks may be organized into bank groups, where each bank group includes one or more banks. Each bank may include multiple of rows and columns. During operations, the memory device may receive a command and an address which specifies one or more rows and one or more columns and then execute the command on the memory cells at the intersection of the specified rows and columns (and/or along an entire row/column). The address may further specify the bank group and/or bank for execution of the command. In some applications, rows may be specified by 17-bit row addresses and columns may be specified by 12-bit column addresses. However, the number of bits used for the addresses may vary depending on the size and/or organization of the memory.

The columns may generally be organized into column planes, each of which includes a number of sets of individual columns all activated by a column select signal (CS) (e.g., column selects). Each bank may include some number X column planes. A column plane may receive some number N of column select (CS) signals, each of which may activate some number M of individual bit lines. As used herein, a column select set or CS set may generally refer to a set of bit lines which are activated by a given value of the CS signal within a column plane. The column select signal may be represented by (all or a portion of) a column address (CA). Responsive to a column select signal, data may be provided from corresponding locations from the column planes. The data from the column planes associated with the column select signal may be referred to as a cache line.

In many applications, multiple memory devices are used by a device and/or computing system. The memory devices may be packaged together in a memory module. For example, single in-line memory modules (SIMMs), dual in-line memory modules (DIMMS), small outline DIMMs (SODIMMs), and rambus in-line memory modules (RIMM) may include multiple memory devices.

FIG. 1A is a block diagram of at least a portion of a computing system. The computing system 10 includes a memory module 12 and a controller 16 in communication with the memory module 12. The memory module 12 may include module logic and buffers 18 and one or more memory devices 14.

The controller 16 may provide commands, addresses (CA), clock signals (CLK), and/or to one or more of the memory devices 14 and receive data from one or more of the memory devices 14. As shown, some or all of the signals transmitted between the controller 16 and memory devices 14 must pass through the module logic and buffers 18. The module logic and buffers 18 may facilitate coordination between the memory devices 14 (e.g., distributing clock signals). However, module logic and buffers 18 may also lead to “middleman” inefficiencies. Further, the module logic and buffers 18 are typically manufactured by an entity different from the entities that manufactured the memory devices 14 and controller 16. This may lead to quality control issues and/or unforeseen compatibility issues. In some instances, this may lead to limitations in error correction capabilities.

### BRIEF DESCRIPTION OF THE DRAWINGS

FIG. 1A is a block diagram of at least a portion of a computing system.

FIG. 1B is a block diagram of at least a portion of a computing system according to some embodiments of the present disclosure.

FIG. 2A is a diagram showing a multi-die device according to an embodiment of the disclosure.

FIG. 2B is a diagram showing a multi-die device according to an embodiment of the disclosure.

FIG. 2C is a block diagram of a semiconductor device according to some embodiments of the present disclosure.

FIG. 3 is a functional block diagram of a memory package according to at least one embodiment of the disclosure.

FIG. 4 is a functional block diagram of a memory package according to at least one embodiment of the disclosure.

FIG. 5 is a functional block diagram of a memory package according to at least one embodiment of the disclosure.

FIG. 6 is a flow chart of a method according to at least one embodiment of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed apparatus, systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A memory package may include a stack of memory devices and at least one buffer die. The buffer die may include components that facilitate communication with a controller and/or host system. The buffer die may include components that facilitate communication between memory packages. The memory packages may be included on a memory module. The buffer die of the memory packages may reduce or eliminate the need for additional devices on memory modules (e.g., buffers, logic). This may reduce reliability and/or compatibility issues in some applications. In some applications, it may provide faster communication between the memory package and the controller and/or host system.

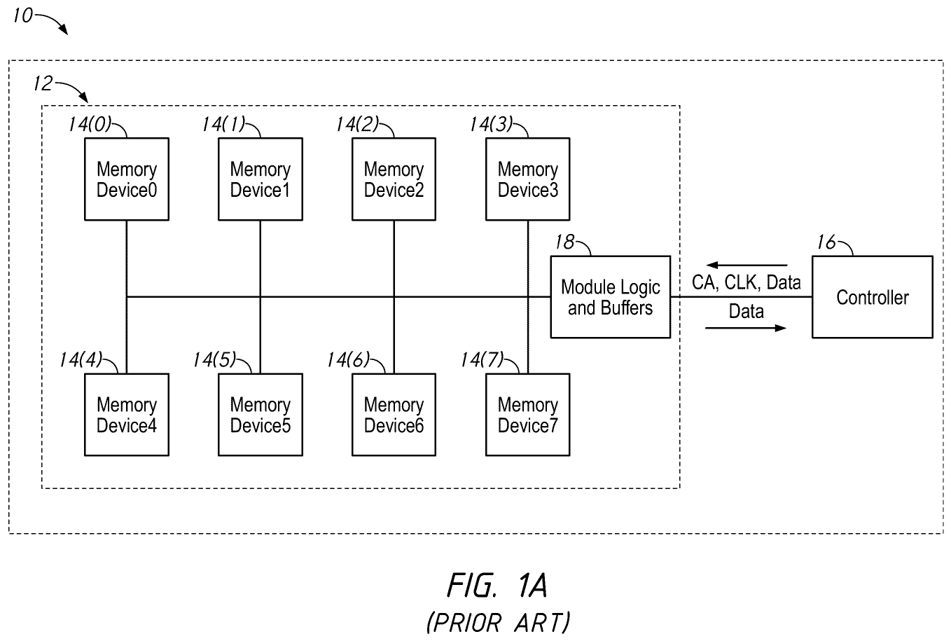

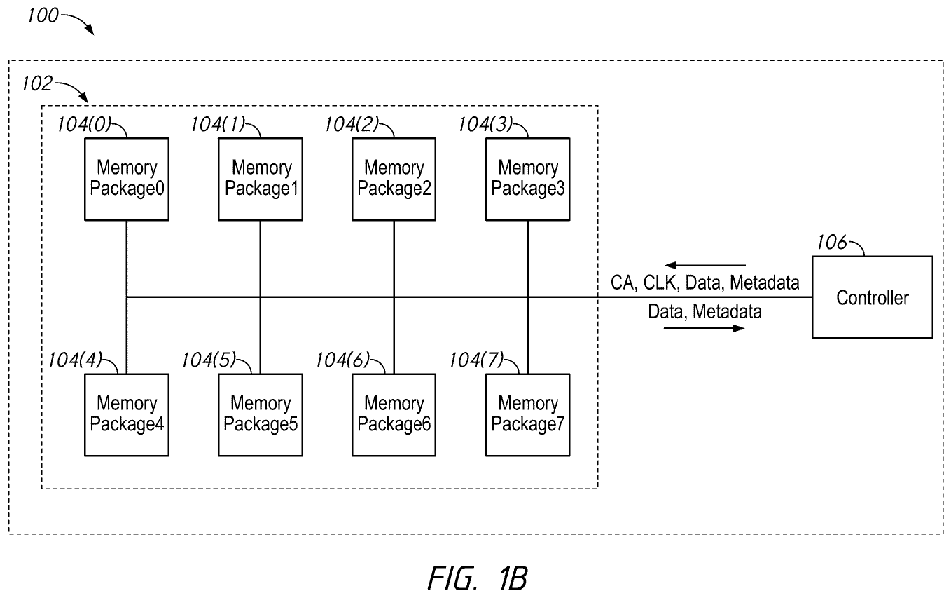

FIG. 1B is a block diagram of at least a portion of a computing system according to some embodiments of the present disclosure. The computing system 100 includes a memory module 102 and a controller 106 in communication with the memory module 102. In some embodiments, the controller 106 may be included in a processor (not shown) or in communication with the processor. The memory module 102 may include one or more memory packages 104. According to embodiments of the present disclosure, each memory package 104 may one or more memory devices and a buffer die. The memory devices may be stacked on the buffer die in some examples. In the example shown in FIG. 1, there are eight memory packages 104(0-7). However, in other embodiments, there may be more or fewer memory packages (e.g., 1 device, 2, devices, 4 devices, 16 devices). In some embodiments, additional memory packages 104 may be included to provide for redundancy. In some embodiments, memory module 102 may be a dual in-line memory module (DIMM). In some embodiments, what is shown in FIG. 1 may represent only half of the DIMM (e.g., one of the two channels). In other words, memory module 102 may include sixteen memory packages 104.

The controller 106 may provide signals such as commands, addresses, clock signals and/or data (e.g., data, metadata, or both) to one or more of the memory packages 104 and receive signals such as data from one or more of the memory packages 104. According to embodiments of the present disclosure, the controller 106 may provide and receive signals from the memory die via the buffer die. In some embodiments, memory package 104 may be x16 or x32 memory devices. That is, either 16 or 32 DQ terminals (e.g., pins) may be active. In some embodiments, the memory package 104 may support both x16 and x32 operation. In some embodiments, whether the memory package 104 operate in x4 or x8 mode may be based, at least in part, on values stored in mode registers (not shown in FIG. 1) of the memory packages 104. In some embodiments, the memory packages 104 may be x4, x8, or x64 memory packages.

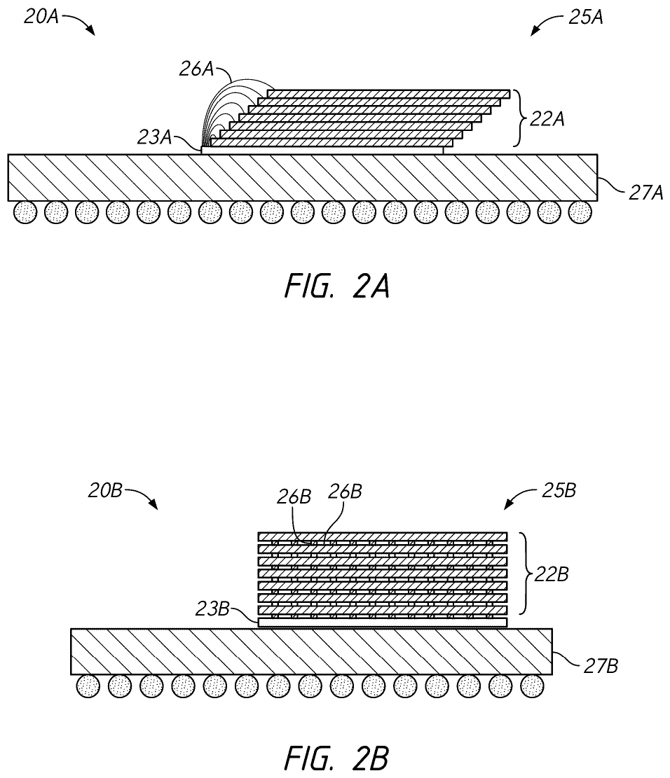

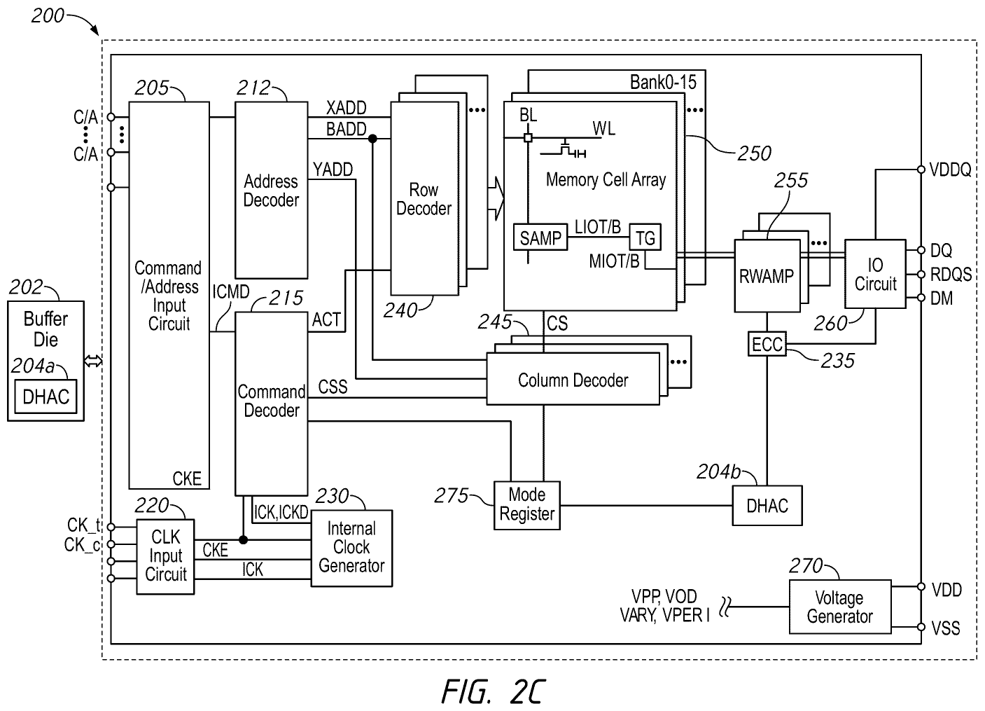

FIG. 2A is a diagram showing a multi-die device according to an embodiment of the disclosure. The multi-die device 20A may include a stack 25A of memory devices 22A (e.g., memory die) and a buffer die 23A. Embodiments of the disclosure are not limited to the particular number of memory devices 22A included in the stack 25A shown in FIG. 2A. For example, the stack 25A may include 1-16 memory devices 22A. Further, while one buffer die 23A is shown in FIG. 2A, in some embodiments, there may be two buffer die 23A per stack 25A. In some embodiments of the disclosure, the stack 25A may be included in one or more of memory packages 104.

The memory devices 22A and buffer die 23A may be stacked in a staggered manner, providing a “shingle-stack” configuration for the stack 25A as shown in FIG. 2A. However, the memory devices 22A and buffer die 23A may be stacked in other configuration such as a staggered configuration. The memory devices 22A and/or buffer die 23A may be attached to one another. In some embodiments of the disclosure, the semiconductor devices 22A are attached to one another by an adhesive epoxy.

The memory devices 22A and/or buffer die 23A may include a pad formation area, a peripheral circuit area, and memory cell array areas (not shown in FIG. 2A) that include memory cells, circuits, and signal lines, for example, sense amplifier circuits, address decoder circuits, data input/output lines, etc. The peripheral circuit area may include various circuits and signal lines for performing various operations. For example, the peripheral circuit area may include command and address input circuits, address and command decoders, clock circuits, power circuits, and input/output circuits. The peripheral circuit area may also include terminals coupled to various circuits of the memory devices 22A and/or buffer die 23A.

The pad formation area may include a plurality of bond pads disposed along the edge of the memory devices 22A and/or buffer die 23A. The plurality of bond pads may be coupled to the terminals of the semiconductor device and represent external terminals of the memory devices 22A and/or buffer die 23A. For example, the plurality of bond pads may include data terminals, command and address terminals, clock terminals, and/or power supply terminals.

Circuits included in the memory cell array area and/or circuits of the peripheral circuit area may be coupled to one or more bond pads included in the pad formation area. Various circuits of the memory devices 22A and/or buffer die 23A may be coupled to the terminals. Conductive structures may be used to couple the terminals to one or more of the bond pads. As a result, the circuits coupled to the terminals are also coupled to the bond pads. The conductive structures may extend from locations of the terminals included in the memory cell array area and/or the peripheral circuit area to the pad formation area.

The memory devices 22A may be offset from one another to allow edge regions of the memory devices 22A to be exposed. The exposed edge regions may include the bond pads to which conductors 26A may be coupled. In some embodiments of the disclosure, the bond pads of the edge regions may be conductive pads. The bond pads may be coupled to terminals of the respective memory device 22A. In some embodiments of the disclosure, the conductors 26A are bond wires. While the conductors 26A in FIG. 2A are shown coupling all of the memory devices 22A to the buffer die 23A, the conductors 26A may be coupled in other configurations. For example, the conductors 26A may couple adjacent memory devices 22A to one another, and the lowest memory device 22A may be coupled to the buffer die 23A by the conductors 26A in a “daisy chain” configuration.

The stack 25A may be attached to a substrate 27A. The stack 25A may be attached to the substrate 27A by an adhesive epoxy in some embodiments of the disclosure. The substrate 27A may include conductive signal lines to route signals along the substrate, for example, to and from the memory devices 22A and/or buffer die 23A. Other circuits may also be attached to the substrate 27A and coupled to the conductive signals lines as well. As a result, the circuits attached to the substrate 27A may be coupled, for example, to the memory devices 22A and/or buffer die 23A through the conductive signal lines of the substrate 27A and conductors coupled to the conductive signal lines and the bond pads of the memory devices 22A and/or buffer die 23A. In some embodiments, the substrate 27A may be included in memory module 102.

FIG. 2B is a diagram showing a multi-die device according to an embodiment of the disclosure. The multi-die device 20B may include a stack 25B of memory devices 22B and a buffer die 23B. Embodiments of the disclosure are not limited to the particular number of memory devices 22B included in the stack 25B shown in FIG. 2B. For example, the stack 25B may include 1-16 memory devices 22B. Further, while one buffer die 23B is shown in FIG. 2B, in some embodiments, there may be two buffer die 23B per stack 25B. In some embodiments of the disclosure, the stack 25B may be included in one or more of the memory packages 104.

The memory devices 22B and/or buffer die 23B may include a pad formation area, a peripheral circuit area, and memory cell array areas (not shown in FIG. 2B) that include memory cells, circuits, and signal lines, for example, sense amplifier circuits, address decoder circuits, data input/output lines, etc. The peripheral circuit area may include various circuits and signal lines for performing various operations. For example, the peripheral circuit area may include command and address input circuits, address and command decoders, clock circuits, power circuits, and input/output circuits. The peripheral circuit area may also include terminals coupled to various circuits of the memory devices 22B and/or buffer die 23B.

The memory devices 22B and buffer die 23B may be stacked in an aligned manner, such that the edges of the memory devices 22B are substantially aligned. When the buffer die 23B is a similar dimension to the memory devices 22B, the buffer die 23B may be substantially aligned with the memory devices 22B as well as shown in FIG. 2B. However, the memory devices 22B and buffer die 23B may be stacked in other configuration such as a staggered configuration.

In contrast to stack 25A, the memory devices 22B and/or buffer die 23B are electrically coupled to one another by through silicon vias (TSVs) 26B rather than being coupled by conductors 26A. In some embodiments, instead of or in addition to pad formation areas, the memory devices 22B and/or buffer die 23B may include TSV formation areas. The memory devices 22B and/or buffer die 23B may be physically attached to one another by additional mechanisms (e.g., not just the TSVs). In some embodiments of the disclosure, the semiconductor devices 22B are attached to one another by an adhesive epoxy.

The stack 25B may be attached to a substrate 27B. The stack 25B may be attached to the substrate 27B by an adhesive epoxy in some embodiments of the disclosure. The substrate 27B may include conductive signal lines to route signals along the substrate, for example, to and from the memory devices 22B and/or buffer die 23B. Other circuits may also be attached to the substrate 27B and coupled to the conductive signals lines as well. As a result, the circuits attached to the substrate 27B may be coupled, for example, to the memory devices 22B and/or buffer die 23B through the conductive signal lines of the substrate 27B and conductors coupled to the conductive signal lines and the bond pads of the memory devices 22B and/or buffer die 23B. In some embodiments, the substrate 27B may be included in memory module 102.

In some embodiments, the buffer die 23A, 23B is a memory device substantially similar to memory devices 22A, 22B. In some embodiments, memory devices 22A, 22B may have certain logic circuits disabled and/or bypassed, and the buffer die 23A, 23B has such logic circuits enabled and acts as a “target” or “master” die. In some embodiments, the buffer die 23A, 23B is a different device with different components than the memory devices 22A, 22B. As described in more detail herein, the memory devices 22A, 22B and/or buffer die 23A, 23B may include components for managing ECC data. In particular, the memory devices 22A, 22B and/or buffer die 23A, 23B may include components to facilitate dynamic allocation of ECC data bits.

According to embodiments of the present disclosure, ECC data bits for different memory devices may be allocated between different memory devices. In some embodiments, memory arrays of the memory devices may be reorganized (e.g., reconfigured) to store more or less ECC data bits. In some embodiments, how many ECC data bits are allocated for a memory device may be based, at least in part, on the error rate of the memory device (e.g., how many errors are detected in the data stored in the memory device). Dynamically allocating ECC data bits between memory devices may allow memory devices with lower error rates to compensate for memory devices with higher error rates. This may allow the memory package to operate without increasing the overall amount of space in the memory package dedicated to ECC data bits in some applications. Dynamically allocating memory array space to ECC data bits may allow each memory device to operate with a desired amount of ECC data bits. For example, memory devices with lower error rates may store less ECC data bits while memory devices with higher error rates may store more ECC data bits. This dynamic allocation of memory array space to ECC data may reduce “wasted” space dedicated to ECC data bits that are not necessary to provide a desired level of data integrity and allow more space for data and/or metadata on the memory device in some applications.

FIG. 2C is a block diagram of a memory device according to some embodiments of the present disclosure. The apparatus may be a semiconductor device. In some embodiments, the memory device 200 may include, without limitation, a dynamic random access (DRAM) device integrated into a single semiconductor chip. In some examples, the DRAM may be a double data rate (DDR) memory device. In some embodiments, it may be a DDR5 or DDR6 memory device. In some embodiments, one or all of the memory devices 22A, 22B of FIGS. 2A and 2B may include memory device 200. While FIG. 2C shows a separate buffer die 202, as noted, in some embodiments, memory device 200 may be a buffer die such as buffer die 202, buffer die 23A, and/or buffer die 23B.

The memory device 200 includes a memory array 250. The memory array 250 includes a plurality of banks BANK0-15, each bank including a plurality of word lines WL, a plurality of bit lines BL, and a plurality of memory cells MC arranged at intersections of the plurality of word lines WL and the plurality of bit lines BL. Although sixteen banks are shown in FIG. 2, memory array 250 may include any number of banks. The selection of the word line WL is performed by a row decoder 240 and the selection of the bit line BL is performed by a column decoder 245. Sense amplifiers (SAMP) are located for their corresponding bit lines BL and connected to at least one respective local I/O line pair (LIOT/B), which is in turn coupled to at least respective one main I/O line pair (MIOT/B), via transfer gates (TG), which function as switches. The TG may be coupled to one or more read/write amplifiers (RWAMP) 255, which may be coupled to an error correction code (ECC) circuit 235. The ECC circuit 235 may be coupled to an IO circuit 260, which may be coupled to one or more external terminals of semiconductor device 200. Read data from the bit line BL is amplified by the sense amplifier SAMP, and transferred to read/write amplifiers 255 over complementary local data lines (LIOT/B), transfer gate (TG), and complementary main data lines (MIOT/B) to the ECC circuit 235. Conversely, write data outputted from the ECC circuit 235 is transferred to the sense amplifier SAMP over the complementary main data lines MIOT/B, the transfer gate TG, and the complementary local data lines LIOT/B, and written in the memory cell MC coupled to the bit line BL.

The memory device 200 may employ a plurality of external terminals that include command and address terminals coupled to a command/address (C/A) bus to receive command and address signals, clock terminals to receive clock signals CK_t and CK_c, data terminals DQ, RDQS, and power supply terminals VDD, VSS, and VDDQ.

The C/A terminals may be supplied with an address and a bank address signal from outside, for example, from a buffer die 202. Buffer die 202 may be buffer die 23A and/or buffer die 23B in some embodiments. The address signal and the bank address signal supplied to the address terminals are transferred, via a command/address input circuit 205, to an address decoder 212. The address decoder 212 receives the address signals and supplies a decoded row address signal XADD to the row decoder 240, and a decoded column address signal YADD to the column decoder 245. The address decoder 212 also receives the bank address signal BADD and supplies the bank address signal to the row decoder 240 and the column decoder 245.

The C/A terminals may further be supplied with command signals from, for example, buffer die 202. In some embodiments, buffer die 202 may receive commands and addresses from a controller, such as controller 106. The command signals may be provided as internal command signals ICMD to a command decoder 215 via the command/address input circuit 205. The command decoder 215 includes circuits to decode the internal command signals ICMD to generate various internal signals and commands for performing operations, for example, a row activation signal (ACT) to select a word line. Another example may be providing internal signals to enable circuits for performing operations, such as control signals to enable signal input buffers that receive clock signals.

Each bank BANK0-15 may be organized into multiple physical column planes (CP). Each column plane may be associated with multiple column selects (e.g., CS0-63, CS0-59, CS0-55). In some embodiments, different column planes may be used to store different types of information. For example, some column planes may store data and another plane stores ECC data. Optionally, a further plane may store global column redundancy (GCR) data. Optionally, the array 250 can store metadata in one or more column planes. In some embodiments, a column plane may store more than one type of information (e.g., data and metadata, metadata and ECC data)

The C/A terminals may receive an access command which is a read command. When a read command is received, and a bank address, a row address and a column address are timely supplied with the read command, a codeword including read data, metadata, and read ECC data (e.g., parity bits) is read from memory cells in the memory array 250 corresponding to the row address and column address. The read command is received by the command decoder 215, which provides internal commands so that read data from the memory array 250 is provided to the ECC circuit 235. The ECC circuit 235 may use the parity bits in the codeword to determine if the codeword includes any errors, and if any errors are detected, may correct them to generate a corrected codeword (e.g., by changing a state of the identified bit(s) which are in error). The corrected codeword is output from the data terminals DQ via the input/output circuit 260.

The C/A terminals may receive an access command which is a write command. When the write command is received, and a bank address, a row address, and a column address are timely supplied as part of the write operation, and write data is supplied through the DQ terminals to the ECC circuit 235. The write data (which may include write data and metadata) supplied to the data terminals DQ is written to a memory cells in the memory array 250 corresponding to the row address and column address. The write command is received by the command decoder 215, which provides internal commands so that the write data is received by data receivers in the input/output circuit 260. The write data is supplied via the input/output circuit 260 to the ECC circuit 235. The ECC circuit 235 may generate ECC data (e.g., a number of parity bits) based on the write data, and the write data and the parity bits may be provided as a codeword to the memory array 250 to be written into the memory cells MC.

While in the examples above, the ECC operations are described as being performed on the memory device 200, in some embodiments, some or all of the ECC operations may be performed by the buffer die 202. In these embodiments, the codewords and/or parity bits may be provided from the memory device 200 to the buffer die 202 during a read operation. The buffer die 202 may include an ECC circuit that detects and corrects errors in the codeword and provides the corrected codeword (without the parity bits) to external DQ terminals. Similarly, during write operations, the buffer die 202 may generate ECC data and provide it to the memory device 200 for storage. In some embodiments where the buffer die 202 includes an ECC circuit, the memory device 200 may not include ECC circuit 235 and/or ECC circuit 235 may be disabled. However in other embodiments, the ECC operations may be divided between the buffer die 202 and memory device 200.

The command decoder 215 may access mode register 275 that is programmed with information for setting various modes and features of operation for the semiconductor device 200. For example, the mode register 275 may provide parameters that allow the semiconductor device 200 to operate at different frequencies, provide different burst lengths, allow banks BANK0-15 to be organized into different groups, operate in x8 or x16 mode, and/or other different operating conditions. In some embodiments, mode register 275 may include multiple registers.

The information in the mode register 275 may be programmed by providing the memory device 200 a mode register write command, which causes the memory device 200 to perform a mode register write operation. In some embodiments, data to be written to the mode register 275 is provided via the C/A terminals and/or the DQ terminals. The command decoder 215 accesses the mode register 275, and based on the programmed information along with the internal command signals provides the internal signals to control the circuits of the semiconductor device 200 accordingly. Information programmed in the mode register 275 may be externally provided by the memory device 200 using a mode register read command, which causes the memory device 200 to access the mode register 275 and provide the programmed information (e.g., to the buffer die 202). In some embodiments, the information may be provided via the C/A terminals and/or the DQ terminals.

Turning to the explanation of the external terminals included in the memory device 200, the clock terminals and data clock terminals are supplied with external clock signals and complementary external clock signals. The external clock signals CK_t, CK_c may be supplied to a clock input circuit 220. When enabled, input buffers included in the clock input circuit 220 pass the external clock signals. For example, an input buffer passes the CK_t and CK_c signals when enabled by a CKE signal from the command decoder 215. The clock input circuit 220 may use the external clock signals passed by the enabled input buffers to generate internal clock signal ICK. The internal clock signal ICK are supplied to internal clock circuit 230 for providing one or more clock signals to the various components of memory device 200.

The internal clock circuits 230 includes circuits that provide various phase and frequency controlled internal clock signals based on the received internal clock signals. For example, the internal clock circuits 230 may include a clock path (not shown in FIG. 2) that receives the ICK clock signal and provides internal clock signals ICK and ICKD to the command decoder 215. Optionally, the input/output circuit 260 may include clock circuits and driver circuits for generating and providing the RDQS signal to a controller.

The power supply terminals are supplied with power supply potentials VDD and VSS. These power supply potentials VDD and VSS are supplied to an internal voltage generator circuit 270. The internal voltage generator circuit 270 generates various internal potentials VPP, VOD, VARY, VPERI. The internal potential VPP is mainly used in the row decoder 240, the internal potentials VOD and VARY are mainly used in the sense amplifiers included in the memory array 250, and the internal potential VPERI is used in many other circuit blocks.

The power supply terminal is also supplied with power supply potential VDDQ. The power supply potentials VDDQ is supplied to the input/output circuit 260 together with the power supply potential VSS. The power supply potential VDDQ may be the same potential as the power supply potential VDD in an embodiment of the disclosure. The power supply potential VDDQ may be a different potential from the power supply potential VDD in another embodiment of the disclosure. However, the dedicated power supply potential VDDQ is used for the input/output circuit 260 so that power supply noise generated by the input/output circuit 260 does not propagate to the other circuit blocks.

According to embodiments of the present disclosure, the buffer die 202 and/or memory device 200 may include a device health analysis circuit (DHAC) 204a, 204b. The DHAC 204a, 204b may receive error data from the ECC circuit 235 and/or an ECC circuit included with the buffer die 202. For example, the ECC circuit 235 may provide a number of errors detected and/or other results of the ECC operations. The DHAC 204a, 204b may analyze the error data and determine that the memory device 200 should have more or less parity bits and/or other ECC data generated and stored. For example, if the error data indicates that a threshold number or over a threshold number of errors are being corrected for the memory device 200, the DHAC 204a, 204b may determine that more ECC data should be generated and stored for the memory device 200 to preserve data integrity. In another example, if the error data indicates that a threshold number or less than a threshold number of errors are being corrected for the memory device 200, the DHAC 204a, 204b may determine that less ECC data can be generated and stored for the memory device 200 while maintaining data integrity. If the error data indicates that the errors are within a certain range, the amount of ECC data may not be adjusted (e.g., may be maintained).

When the DHAC 204a, 204b determines additional ECC data should be stored, in some embodiments, the memory array 250 may be reorganized to store the additional ECC data. For example, space dedicated to data and/or metadata may be reassigned to store ECC data. In other embodiments, another memory device with a lower error rate may be assigned to store the additional ECC data for memory device 200.

When the DHAC 204a, 204b determines less ECC data is required, in some embodiments, the memory array 250 may be configured to store less ECC data and store more data and/or metadata. In other embodiments, the memory array 250 may be configured to store additional ECC data from other memory devices with higher error rates.

In some embodiments, the DHAC 204a, 204b may provide signals to the mode register 275 in order to reorganize the memory array 250. For example, the mode register 275 may store one or more values that determine the organization of the memory array 250 (e.g., number of planes dedicated to metadata, data, and/or ECC data, size of the planes, which portions of planes are dedicated to different types of data, etc.). In some embodiments, the control signals from DHAC 204a, 204b may cause one or more values to be written to the mode register 275 which may cause the memory array 250 to be organized to store desired amount of ECC data.

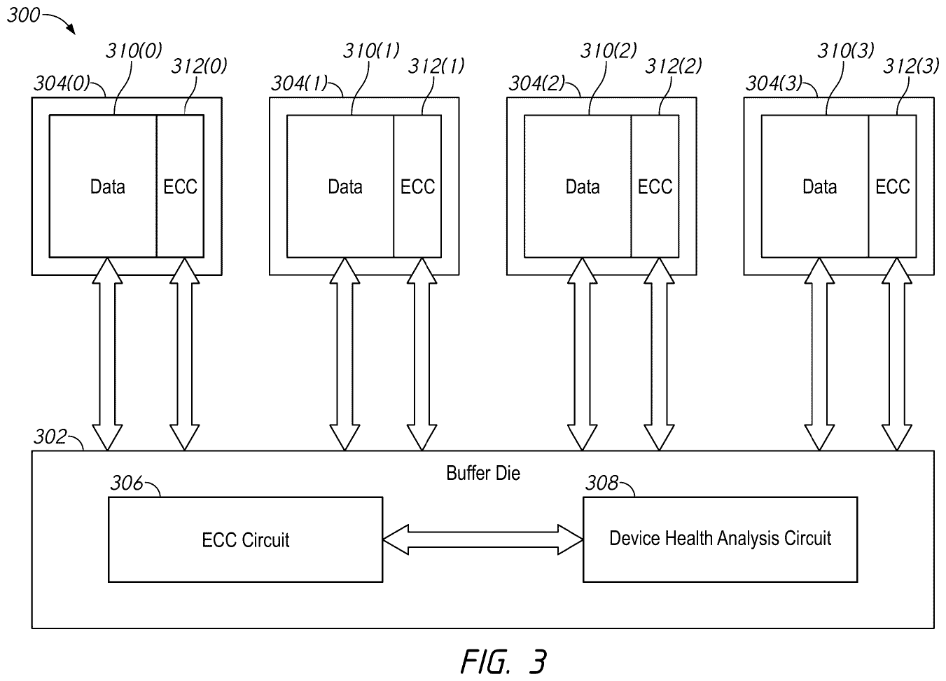

FIG. 3 is a functional block diagram of a memory package according to at least one embodiment of the disclosure. Memory package 300 may include a buffer die 302 and one or more memory devices 304. While four memory devices 304(0-3) are shown in FIG. 3, any number of memory devices 304 may be included. In some embodiments, the memory devices 304 may include memory device 200 shown in FIG. 2C. Each memory device 304 may include a memory array (e.g., memory array 250) that may include a portion configured to store data 310 and a portion configured to store ECC data 312. In some embodiments, the data portion 310 and/or ECC data portion 312 may include one or more column planes. In some embodiments, buffer die 302 may include buffer die 202, buffer die 23A, and/or buffer die 23B. In some embodiments, the memory package 300 may be used to implement one or more of memory packages 104 shown in FIG. 1B. FIG. 3 is a functional block diagram, and the arrangement of the components is to illustrate the passing of information between components and is not meant to reflect the physical arrangement of the components.

Memory devices 304 may generate and store ECC data (e.g., parity bits) in the ECC data portion 312 to improve data integrity. In some embodiments, memory devices 304 may store sixteen bits of ECC data per cache line. The sixteen bits may be stored in one or more column planes. The ECC data may be used to correct errors in the data (e.g., stored in the data portion 310) of the cache line. For example, the ECC data along with the data and/or metadata may form a codeword that is used to detect errors in the data and/or metadata. According to some embodiments of the present disclosure, not all of the ECC data stored on the memory device 304 may be used to correct errors in data from that particular memory device 304.

The buffer die 302 may include an ECC circuit 306 and a device health analysis circuit 308. In some embodiments, device health analysis circuit 308 may be included in DHAC 204a. In some embodiments, the ECC circuit 306 may perform error correction on data received from the memory devices 304 based on the ECC data also provided by the memory devices 304. This may be done in addition to ECC operations performed on the memory devices 304 or instead of having the ECC operations performed on the memory devices 304. In examples where the ECC circuit 306 performs all of the ECC operations, the ECC circuit of the memory devices 304 (not shown in FIG. 3, see ECC circuit 235 in FIG. 2C) may be omitted or disabled. In other embodiments, the ECC circuit 306 may receive error data such as results of the ECC operations performed by the memory devices 304. For example, the error data may include the number and/or locations of errors detected in the memory devices 304. In embodiments where the ECC circuit 306 performs the ECC operations, the ECC circuit 306 may generate the results.

The ECC operation results and/or other error data may be provided to a device health analysis circuit (DHAC) 308 on the buffer die 302. The DHAC 308 may use the error data to determine the number of errors on the memory devices 304(0-3). In some embodiments, the DHAC circuit 308 may compare a number of errors on a memory device 304 to a threshold value. In some embodiments, the DHAC 308 may have storage to keep a record of a number of errors for each memory device 304(0-3). The record may be used to determine trends of the memory devices 304(0-3) (e.g., increasing number of errors, steady number of errors). Based on the comparison to the threshold value and/or analysis of the error trend, the DHAC 308 may determine a number of ECC data bits that should be utilized to correct errors for the memory devices 304(0-3).

Based on the determination from the DHAC 308, the ECC circuit 306 may allocate the ECC data bits stored on each memory device 304 between the devices. For example, while sixteen ECC data bits may be generated and/or stored in some embodiments as a “default,” eight bits may be sufficient to correct one error and detect two errors for a cache line of 128 bits. For example, if memory device 304(0) has zero or one error, sixteen ECC data bits may not be required to preserve the data integrity of memory device 304(0). If the DHA circuit 308 determines that memory device 304(1) has multiple errors, additional ECC data bits may be needed to correct the errors and preserve data integrity for memory device 304(1). Continuing this example, according to embodiments of the present disclosure, memory device 304(0) may store eight bits of ECC data to correct errors in data stored on memory device 304(0). Further, memory device 304(0) may store eight bits of ECC data to correct errors in data stored on memory device 304(1). Thus, memory device 304(1) may have twenty-four ECC data bits available to correct errors in the data stored on memory device 304(1): 16 ECC bits stored on memory device 304(1) and 8 ECC bits stored on memory device 304(0). This is merely one example, and other allocations of ECC bits between memory devices 304 is possible. For example, memory device 304(0) may include 12 ECC bits for correcting errors on memory device 304(0) and store 4 ECC bits for correcting errors on memory device 304(1). Thus, memory device 304(1) may have 20 ECC bits for correcting errors.

In embodiments where the memory devices 304(0-3) perform the ECC operations, the ECC circuit 306 may facilitate passing ECC bits from one memory device 304 to another memory device 304 such that the ECC circuits of the memory devices 304 can utilize the additional ECC data bits for ECC operations. In embodiments where the ECC circuit 306 performs the ECC operations, the ECC circuit 306 may receive all of the ECC data from the memory devices 304(0-3) and assign the ECC bits to the data from the different memory devices 304(0-3) for performing the ECC operations.

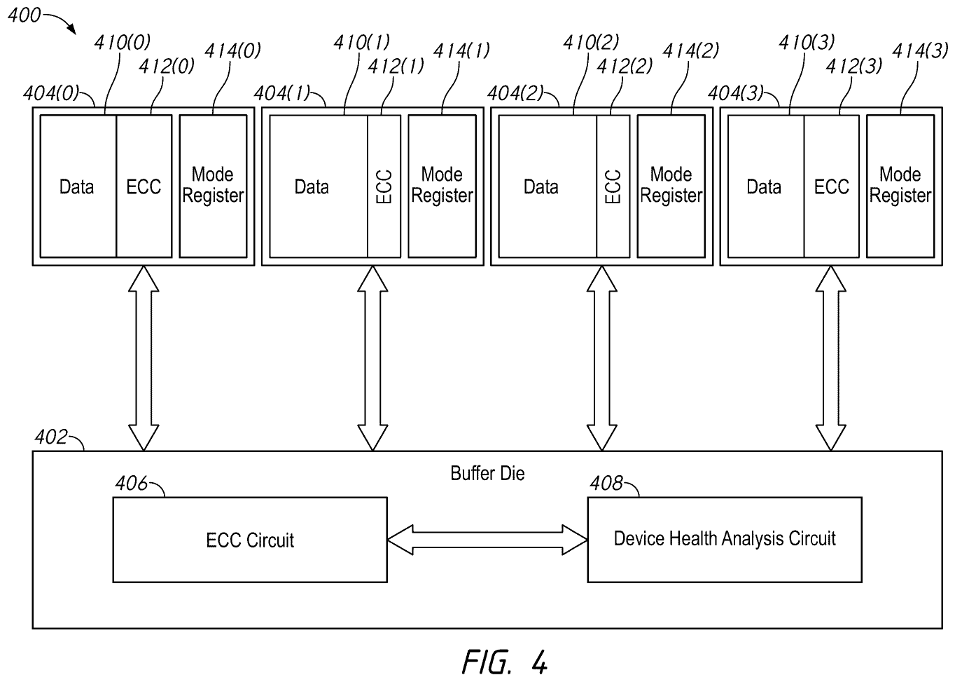

FIG. 4 is a functional block diagram of a memory package according to at least one embodiment of the disclosure. Memory package 400 may include a buffer die 402 and one or more memory devices 404. While four memory devices 404(0-3) are shown in FIG. 4, any number of memory devices 404 may be included. In some embodiments, the memory devices 404(0-3) may include memory device 200 shown in FIG. 2C. Each memory device 404(0-3) may include a memory array (e.g., memory array 250) that may include a portion configured to store data 410 and a portion configured to store ECC data 412. In some embodiments, the data portion 410 and/or ECC data portion 412 may include one or more column planes. In some embodiments, the data portion 410 may include both data and metadata. In some embodiments, the data and metadata may be stored in separate column planes of the data portion 410. Each memory device 404(0-3) may include a mode register 414(0-3). In some embodiments, mode register 414 may be included in mode register 275. In some embodiments, buffer die 402 may include buffer die 202, buffer die 23A, and/or buffer die 23B. In some embodiments, the memory package 400 may be used to implement one or more of memory packages 104 shown in FIG. 1B. FIG. 4 is a functional block diagram, and the arrangement of the components is to illustrate the passing of information between components and is not meant to reflect the physical arrangement of the components.

Memory devices 404 may generate and store ECC data (e.g., parity bits) in the ECC data portion 412 to improve data integrity. In some embodiments, memory devices 404 may default to storing sixteen bits of ECC data per cache line, but other default amounts may be used (e.g., 8 bits). The sixteen bits may be stored in one or more column planes of the ECC data portion 412. The ECC data may be used to correct errors in the data (e.g., stored in the data portion 410) of the cache line. For example, the ECC data along with the data and/or metadata may form a codeword that is used to detect errors in the data and/or metadata. According to some embodiments of the present disclosure, the amount of space dedicated to ECC data in the memory array may be changed (e.g., dynamic).

The buffer die 402 may include an ECC circuit 406 and a device health analysis circuit 408. In some embodiments, device health analysis circuit 408 may be included in DHAC 204a. In some embodiments, the ECC circuit 406 may perform error correction on data received from the memory devices 404 based on the ECC data also provided by the memory devices 404. This may be done in addition to ECC operations performed on the memory devices 404 or instead of having the ECC operations performed on the memory devices 404. In examples where the ECC circuit 406 performs all of the ECC operations, the ECC circuit of the memory devices 404 (not shown in FIG. 4, see ECC circuit 235 in FIG. 2C) may be omitted or disabled. In other embodiments, the ECC circuit 406 may receive error data such as results of the ECC operations performed by the memory devices 404. For example, the error data may include the number and/or locations of errors detected in the memory devices 404. In embodiments where the ECC circuit 406 performs the ECC operations, the ECC circuit 406 may generate the results.

The ECC operation results and/or other error data may be provided to a device health analysis circuit (DHAC) 408 on the buffer die 402. The DHAC 408 may use the error data to determine the number of errors on the memory devices 404(0-3). In some embodiments, the DHAC circuit 408 may compare a number of errors on a memory device 404 to a threshold value. In some embodiments, the DHAC 408 may have storage to keep a record of a number of errors for each memory device 404(0-3). The record may be used to determine trends of the memory devices 404(0-3) (e.g., increasing number of errors, steady number of errors). Based on the comparison to the threshold value and/or analysis of the error trend, the DHAC 408 may determine a number of ECC data bits that should be utilized to correct errors for the memory devices 404(0-3).

Based on the determination from the DHAC 408, the buffer die 402 may organize the memory array one or more of the memory devices 404(0-3) to store more or less ECC data bits. For example, if the DHA circuit 408 determines that memory device 404(1) has a number of errors below a threshold value, the DHA circuit 408 may reorganize the memory array to allocate less space in the memory array to ECC data bits and allocate more space in the memory array to data and/or metadata. In other words, the buffer die 402 may change the size of the data portion 410(1) and/or the ECC data portion 412(1). In the example shown, the ECC data portion 412(1) is smaller than the ECC data portion 412(0). This may allow more space to be available for storing data and/or metadata on memory device 404(1) compared to memory device 404(0). For example, the default number of ECC data bits may be 16, and memory devices 404 found to have low error rates may be reorganized to only store 8 bits of ECC data.

In another example, if the DHA circuit 408 determines that memory device 304(0) has a number of errors above a threshold value, the DHA circuit 408 may reorganize the memory array to allocate more space in the memory array to ECC data bits and allocate less space in the memory array to data and/or metadata. In FIG. 4, the ECC data portion 412(0) is larger than the ECC data portion 412(1). This may reduce space available for storing data and/or metadata on memory device 404(0) compared to memory device 404(1). However, it may allow memory device 404(0) to continue to operate at acceptable data integrity levels. For example, the default number of ECC data bits may be 8, and memory devices 404 found to have high error rates may be reorganized to store 16 bits of ECC data. In different example, the default number of ECC data bits may be 16, and memory devices 404 found to have high error rates may be reorganized to store 24 bits or 32 bits of ECC data.

In some embodiments, the reorganization of the memory array may only affect the amount of metadata stored in the data portion 410, and not the amount of data stored. For example, one or more planes or portions of one or more planes that store metadata may be reallocated to storing ECC data bits (e.g., assigned to the ECC data portion 412). However, in other embodiments, data and/or both data and metadata space may be affected by changing the number of ECC data bits stored in the memory device 404.

In some embodiments, the device health analysis circuit 408 may provide one or more control signals to the mode registers 414 of the memory devices 404 to reorganize the memory arrays of said memory devices 404. The control signals may cause one or more values to be written to the mode registers 414 to cause the memory array of the memory device 404 to be reorganized (e.g., more or fewer ECC data bits stored). Of course, if the device health analysis circuit 408 determines the error rate of a memory device 404 is within an acceptable range, no reallocation of the memory array may occur.

Alternatively, in some embodiments, device health analysis circuit 408 may provide the error data or analysis of the error data to an external device such as controller 106. The controller may use the information provided by the device health analysis circuit 408 to determine whether to reorganize the memory array of one or more of the memory devices 404. The controller may provide control signals (e.g., mode register write commands and values to be written) to the mode register 414 and/or the device health analysis circuit 408 to cause the memory array of the memory device 404 to be reorganized to store more or fewer ECC data bits.

In some implementations, the embodiments shown in FIGS. 3 and 4 may be combined. For example, in addition to dynamically allocating memory array space of a memory device to ECC data bits as described with reference to FIG. 4, the memory device may also store ECC data bits for another memory device in the memory package. For example, a first memory device may have its memory array reorganized to store 16 bits of ECC data instead of 8 bits of ECC data and the additional space may be used to store 8 bits of ECC data from a second memory device. Other combinations of the embodiments shown in FIGS. 3 and 4 may be used in other implementations.

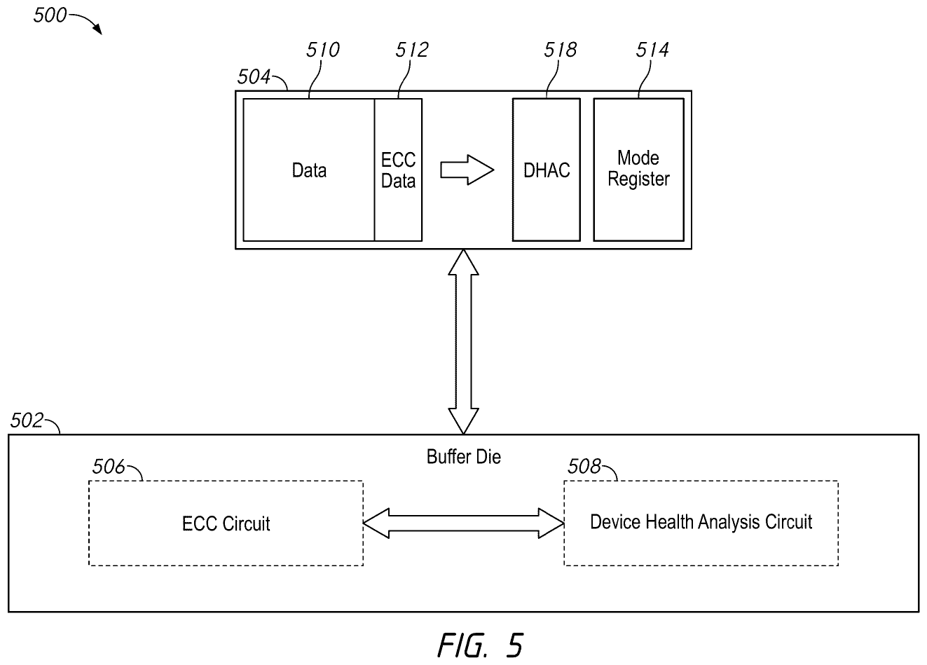

FIG. 5 is a functional block diagram of a memory package according to at least one embodiment of the disclosure. FIG. 5 is a functional block diagram, and the arrangement of the components is to illustrate the passing of information between components and is not meant to reflect the physical arrangement of the components. Memory package 500 may include a buffer die 502 and one or more memory devices 504. While one memory device 504 is shown in FIG. 5, any number of memory devices 504 may be included.

In some embodiments, the memory device 504 may include memory device 200 shown in FIG. 2C. The memory device 504 may include a memory array (e.g., memory array 250) that may include a portion configured to store data 510 and a portion configured to store ECC data 512. In some embodiments, the data portion 510 and/or ECC data portion 512 may include one or more column planes. In some embodiments, the data portion 510 may include both data and metadata. In some embodiments, the data and metadata may be stored in separate column planes of the data portion 510. The memory device 504 may include a mode register 514. In some embodiments, mode register 514 may be included in mode register 275. The memory device 504 may include a device health analysis circuit (DHAC) 518. DHAC 518 may be included in DHAC 204b in some embodiments. In some embodiments, buffer die 502 may include buffer die 202, buffer die 23A, and/or buffer die 23B. In some embodiments, the memory package 500 may be used to implement one or more of memory packages 104 shown in FIG. 1B.

Memory device 504 may generate and store ECC data (e.g., parity bits) in the ECC data portion 512 to improve data integrity. In some embodiments, memory devices 504 may default to storing sixteen bits of ECC data per cache line, but other default amounts may be used. The sixteen bits may be stored in one or more column planes of the ECC data portion 512. The ECC data may be used to correct errors in the data (e.g., stored in the data portion 510) of the cache line. For example, the ECC data along with the data and/or metadata may form a codeword that is used to detect errors in the data and/or metadata. According to some embodiments of the present disclosure, the amount of space dedicated to ECC data in the memory array may be changed (e.g., dynamic).

The buffer die 502 may optionally include an ECC circuit 506 and/or a device health analysis circuit 508. In some embodiments, device health analysis circuit 508 may be included in DHAC 204a. In some embodiments, the ECC circuit 506 may perform error correction on data received from the memory device 504 based on the ECC data also provided by the memory device 504. This may be done in addition to ECC operations performed on the memory device 504 or instead of having the ECC operations performed on the memory device 504. In examples where the ECC circuit 506 performs all of the ECC operations, the ECC circuit of the memory device 504 (not shown in FIG. 5, see ECC circuit 235 in FIG. 2C) may be omitted or disabled. In other embodiments, the ECC circuit 506 may receive error data such as results of the ECC operations performed by the memory device 504. For example, the error data may include the number and/or locations of errors detected in the memory device 504. In embodiments where the ECC circuit 506 performs the ECC operations, the ECC circuit 506 may generate the results. However, in other embodiments where the memory device 504 performs the ECC operations, the ECC circuit 506 may be omitted or disabled.

The ECC operation results and/or other error data may be provided to the DHAC 518 on the memory device 504. The DHAC 518 may use the error data to determine the number of errors on the memory device 504. In some embodiments, the DHAC 518 may compare a number of errors on a memory device 504 to a threshold value. In some embodiments, the DHAC 518 may have storage to keep a record of a number of errors for the memory device 504. The record may be used to determine trends of the memory device 504 (e.g., increasing number of errors, steady number of errors). Based on the comparison to the threshold value and/or analysis of the error trend, the DHAC 518 may determine a number of ECC data bits that should be utilized to correct errors for the memory device 504.

Based on the determination from the DHAC 518, the memory device 504 may organize the memory array to store more or less ECC data bits. For example, if the DHA circuit 518 determines that memory device 504 has a number of errors below a threshold value, the DHA circuit 518 may reorganize the memory array to allocate less space in the memory array to ECC data bits and allocate more space in the memory array to data and/or metadata. For example, the default number of ECC data bits may be 16, and when memory device 504 is found to have low error rates, memory device 504 may be reorganized to only store 8 bits of ECC data.

In another example, if the DHA circuit 518 determines that memory device 504 has a number of errors above a threshold value, the DHA circuit 518 may reorganize the memory array to allocate more space in the memory array to ECC data bits and allocate less space in the memory array to data and/or metadata. For example, the default number of ECC data bits may be 8, and when memory device 504 is found to have high error rates, it may be reorganized to store 16 bits of ECC data. In different example, the default number of ECC data bits may be 16, and when memory device 504 is found to have high error rates, it may be reorganized to store 24 bits or 32 bits of ECC data.

In some embodiments, the reorganization of the memory array may only affect the amount of metadata stored in the data portion 510, and not the amount of data stored. For example, one or more planes or portions of one or more planes that store metadata may be reallocated to storing ECC data bits (e.g., assigned to the ECC data portion 512). However, in other embodiments, data and/or both data and metadata space may be affected by changing the number of ECC data bits stored in the memory device 504.

In some embodiments, the device health analysis circuit 518 may provide one or more control signals to the mode register 514 of the memory device 504 to reorganize the memory arrays of said memory device 504. The control signals may cause one or more values to be written to the mode register 514 to cause the memory array of the memory device 504 to be reorganized (e.g., more or fewer ECC data bits stored). Of course, if the device health analysis circuit 518 determines the error rate of a memory device 504 is within a range, no reallocation of the memory array may occur. For example, if the number of errors is equal to or below an upper threshold value and equal to or above a lower threshold value, the size of the ECC data portion and the data portion may remain unchanged.

Alternatively, in some embodiments, DHAC 518 may provide the error data or analysis of the error data to DHAC 508 on the buffer die 502. The DHAC 508 may use the information provided by the memory device 504 (alone or in combination with data received from the DHAC of other memory die in the memory package 500) to determine whether to reorganize the memory array of the memory device 504. The DHAC 508 (e.g., mode register write commands and values to be written) to the mode register 514 and/or the device health analysis circuit 518 to cause the memory array of the memory device 504 to be reorganized to store more or fewer ECC data bits. Alternatively, the DHAC 508 may further provide the information to an external device, such as a controller, which may provide control signals for reorganizing the memory array of memory device 504.

In the example shown in FIG. 5, each memory device, such as memory device 504, in a memory package may dynamically allocate space in its memory array to ECC data bits independently of a buffer die, such as buffer die 502. Alternatively, the memory devices in a memory system may interact with the buffer die to dynamically allocate space in the memory array to ECC data bits.

In some implementations, the embodiment shown in FIG. 5 may be combined with the embodiments shown in FIGS. 3 and/or 4. For example, DHAC 508 and DHAC 518 may both perform analysis of error data and share analysis results to determine the amount of space that should be allocated in a memory device's memory array for ECC data bits. In another example, the DHAC 518 and/or DHAC 508 may determine an amount of that should be allocated in a memory device's memory array for ECC data bits, and how many of those ECC data bits are for the memory device and how many ECC data bits are for another memory device in the memory package. Other combinations of the embodiments shown in FIGS. 3-5 may be used in other implementations.

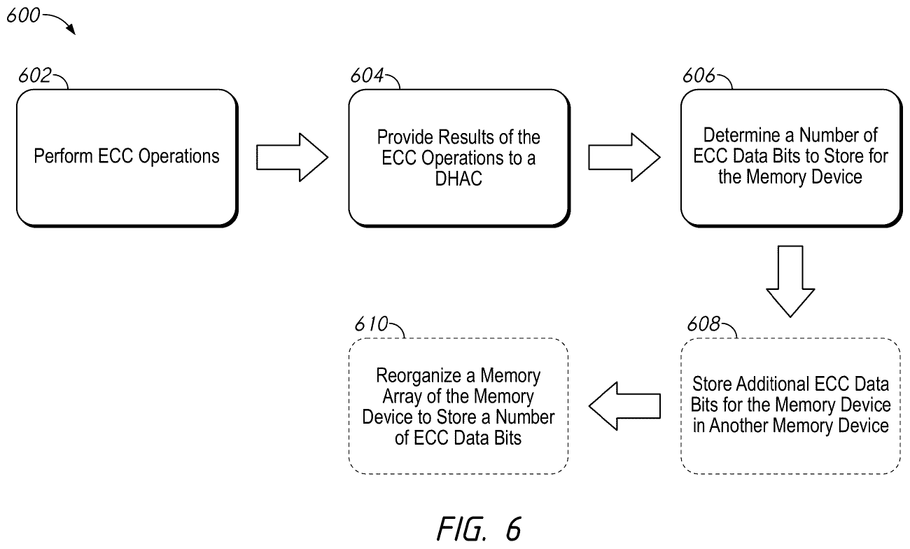

FIG. 6 is a flow chart of a method according to at least one embodiment of the present disclosure. The method shown in flowchart 600 may be performed in whole or in part by a buffer die and/or a memory device as described in one or more embodiments disclosed herein.

At block 602 “perform ECC operations” may be performed. In some embodiments, the ECC operations may be performed by a memory device or a buffer die of a memory package. In some embodiments, both the memory device and the buffer die may perform ECC operations.

At block 604 “provide results of the ECC operations to a DHAC” may be performed. The results may include error data (e.g., number of errors found in the data), and may be provided by the ECC circuit to the DHAC. In some embodiments, the DHAC may be included on the buffer die or the memory device. In some embodiments, both the buffer die and memory device may include DHACs.

At block 606, “determine a number of ECC data bits to store for the memory device” may be performed. The determination may be made by the DHAC in some embodiments.

In some embodiments, block 608 may be performed where “store additional ECC data bits for the memory device in another memory device” is performed. For example, as described with reference to FIG. 3.

In some embodiments, block 610 may be performed where “reorganize a memory array of the memory device to store a number of ECC data bits” may be performed. In some instances, the number of ECC data bits may be greater than or less than a number currently stored in the memory array. In this case, a size of a portion of the memory array that stores data and a size of a portion of the memory array that stores ECC data may change. If the number of ECC data bits to store remains the same as the number currently stored, block 610 may not be performed.

The apparatuses, systems, and methods disclosed herein may allow for dynamic allocation of ECC data bits between memory devices of a memory package and/or dynamically allocate memory array space within a memory device to ECC data bits. Dynamically allocating ECC data bits between memory devices may allow memory devices with lower error rates to compensate for memory devices with higher error rates. This may allow the memory package to operate without increasing the overall amount of space in the memory package dedicated to ECC data bits in some applications. Dynamically allocating memory array space to ECC data bits may allow each memory device to operate with a desired amount of ECC data bits. For example, memory devices with lower error rates may store less ECC data bits while memory devices with higher error rates may store more ECC data bits. This dynamic allocation of memory array space to ECC data may reduce “wasted” space dedicated to ECC data bits that are not necessary to provide a desired level of data integrity and allow more space for data and/or metadata on the memory device in some applications.

Of course, it is to be appreciated that any one of the examples, embodiments or processes described herein may be combined with one or more other examples, embodiments and/or processes or be separated and/or performed amongst separate devices or device portions in accordance with the present systems, devices and methods. For example, a buffer die may have all or some of the features of the buffer dice disclosed in the present application.

Finally, the above discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a plurality of memory devices; and
a buffer die in communication with the plurality of memory devices, wherein the buffer die is configured to allocate error correction code (ECC) data between the plurality of memory devices.

2. The apparatus of claim 1, wherein the buffer die is further configured to perform ECC operations.

3. The apparatus of claim 1, wherein the plurality of memory devices are configured to perform ECC operations.

4. The apparatus of claim 1, wherein the buffer die comprises a device health analysis circuit configured to determine a number of ECC data bits to allocate to a memory device of the plurality of memory devices.

5. The apparatus of claim 4, wherein the number of ECC data bits to allocate to the memory device is based, at least in part, on a number of errors detected in the memory device.

6. The apparatus of claim 1, wherein a memory device of the plurality of memory devices stores ECC data for the memory device and at least one other memory device of the plurality of memory devices.

7. An apparatus comprising:
a plurality of memory devices, wherein each memory device comprises a memory array having a data portion configured to store data and an error correction code (ECC) portion configured to store ECC data; and
a buffer die in communication with the plurality of memory devices, wherein the buffer die is configured to organize the memory array to change a size of the data portion and a size of the ECC portion.

8. The apparatus of claim 7, wherein the buffer die comprises a device health analysis circuit (DHAC) configured to determine a number of ECC data bits to store in a memory device of the plurality of memory devices, wherein the size of the data portion and the size of the ECC portion are determined based, at least in part, on the number of ECC data bits.

9. The apparatus of claim 8, wherein the number of ECC data bits is based a number of errors detected in the memory device.

10. The apparatus of claim 8, wherein each of the plurality of memory devices further comprises an ECC circuit configured to perform ECC operations and provide results of the ECC operations to the DHAC.

11. The apparatus of claim 8, wherein the buffer die further comprises an ECC circuit configured to perform ECC operations and provide results of the ECC operations to the DHAC.

12. The apparatus of claim 8, wherein the buffer die is configured to provide the number of ECC data bits to store to an external device.

13. The apparatus of claim 7, wherein each of the plurality of memory devices further comprises a mode register, wherein the buffer die is configured to provide a control signal to the mode register to organize one or more of the memory arrays of the plurality of memory devices.

14. The apparatus of claim 13, wherein at least one value written to the mode register based on the control signal determines the size of the data portion and the size of the ECC portion.

15. An apparatus comprising:
a memory array comprising a data portion configured to store data and an error correction code (ECC) portion configured to store ECC data;
an ECC circuit configured to perform ECC operations; and
a device health analysis circuit (DHAC) configured to determine a number of ECC data bits to store in the memory array based, at least in part, on results of the ECC operations and organize the memory array to change a size of the data portion and a size of the ECC portion based, at least in part, on the number of ECC data bits.

16. The apparatus of claim 15, further comprising a mode register, wherein the buffer die is configured to provide a control signal to the mode register to organize the memory array and the control signal determines the size of the data portion and the size of the ECC portion.

17. The apparatus of claim 15, wherein the number of ECC data bits to store in the memory device is less when the results of the ECC operations indicate a number of errors less than or equal to a first threshold value; and
wherein the number of ECC data bits to store in the memory device is greater when the results of the ECC operations indicate the number of errors is greater than or equal to a second threshold value.

18. The apparatus of claim 17, wherein DHAC is configured not to change the size of the data portion nor the size of the ECC portion when the number of errors is between the first threshold value and the second threshold value.

19. The apparatus of claim 15, further comprising:
a memory device including the memory array, the ECC circuit, and the DHAC; and
a buffer die coupled to the memory device.

20. The apparatus of claim 19, further comprising a memory package including the buffer die and further comprising a plurality of memory devices, wherein the memory device is one of the plurality of memory devices, and the plurality of memory devices are coupled to the buffer die.

21. The apparatus of claim 20, further comprising a memory module comprising a plurality of memory packages, wherein the memory package is included in the plurality of memory packages.
